(19) United States
(12) Patent Application Publication
(10) Pub. No.: US 2009/0183773 A1
(43) Pub. Date: Jul. 23, 2009

(54) AMINE-NEUTRALIZED IONOMER ENCAPSULANT LAYERS AND SOLAR CELL LAMINATES COMPRISING THE SAME

(75) Inventors: Sam Louis Samuels, Landenberg, PA (US); Richard Allen Hayes, Beaumont, TX (US)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(73) Assignee: E.I. du Pont de Nemours and Company, Wilmington, DE (US)

(21) Appl. No.: 12/017,241

(22) Filed: Jan. 21, 2008

(51) Int. Cl. H01L 31/04; B32B 37/00; B32B 38/00

(52) U.S. Cl. 136/259; 156/285; 156/60

(57) ABSTRACT

A solar cell pre-lamination assembly comprises an amine-neutralized ionomer film or sheet and a solar cell module that is prepared therefrom.

The invention relates to an encapsulant film or sheet comprising an amine-neutralized ionomer composition and a solar cell laminate comprising the same.

### BACKGROUND OF THE INVENTION

As a sustainable energy resource, the use of solar cell modules is rapidly expanding. One preferred way of manufacturing a solar cell module involves forming a pre-lamination assembly comprising at least 5 structural layers. The solar cell pre-lamination assemblies are constructed in the following order starting from the top, or incident layer (that is, the layer first contacted by light) and continuing to the backing layer (the layer furthest removed from the incident layer): (1) incident layer (typically a glass plate or a thin polymeric film (such as a fluoropolymer or polyester film), but could conceivably be any material that is transparent to sunlight), (2) front encapsulant layer, (3) solar cell component, (4) back encapsulant layer, and (5) backing layer.

The encapsulant layers are designed to encapsulate and protect the fragile solar cell component. Generally, a solar cell pre-lamination assembly incorporates at least two encapsulant layers sandwiched around the solar cell component. Suitable polymeric materials used in the solar cell encapsulant layers would typically possess a combination of characteristics such as high transparency, low haze, high impact resistance, high penetration resistance, good ultraviolet (UV) light resistance, good long term thermal stability, adequate adhesion strength to glass and other rigid polymeric sheets, high moisture resistance, and good long term weatherability. In addition, the optical properties of the front encapsulant layer may be such that light can be effectively transmitted to the solar cell component.

Ionomers, which are derived from partially or fully neutralized acid copolymers of α-olefins and α,β-ethylenically unsaturated carboxylic acids, have been known and used in glass laminates for years. See e.g., U.S. Pat. Nos. 3,344,014, 4,799,346, 4,906,703, and 5002820. Solar cell encapsulant layers derived from ionomers that are neutralized with inorganic metal ions have also been disclosed in, e.g., U.S. Pat. Nos. 5,476,553; 5,478,402; 5,733,382; 5,762,720; 5,986,203; 6,114,046; and 6660930, US Pat. Appl. Nos. 2003/0000568; 2005/0279401; 2006/0084763; and 2006/0165929, and Japanese Pat Nos. JP 2000186114 and JP 2006032308. However, the solar cell encapsulant layers formed of such ionomers are often associated with low transparency, low adhesion and/or inadequate thermostability.

### SUMMARY OF THE INVENTION

The invention is directed to a solar cell pre-lamination assembly comprising a film or sheet comprising an amine-neutralized ionomer composition and a solar cell component comprising or formed of one or a plurality of electronically interconnected solar cells, wherein, (a) the solar cell component has a light-receiving side that faces a light source and a back side that is opposite from the light source; and (b) the amine-neutralized ionomer is derived from an acid copolymer that (i) comprises, based on the total weight of the acid copolymer, copolymerized units of an α-olefin having 2 to 10 carbons and about 9 to about 35 wt % of an α,β-ethylenically unsaturated carboxylic acid having 3 to 8 carbons and (ii) is about 1% to about 90%, based on the total carboxylic acid content of the acid copolymer, neutralized with one or more neutralizing agents that include one or more amines.

The invention is further directed to a process comprising:

(i) providing a solar cell pre-lamination assembly as described above and
(ii) laminating the assembly to form a solar cell module.

### DETAILED DESCRIPTION OF THE INVENTION

### Amine-Neutralized Ionomers

The term “acid copolymer” refers to a polymer comprising copolymerized units of an α-olefin, an α,β-ethylenically unsaturated carboxylic acid, and optionally other suitable comonomer(s) such as, an α,β-ethylenically unsaturated carboxylic acid ester.

The term “ionomer” refers to a polymer that is derived from a parent acid copolymer, as disclosed above, by partially or fully neutralizing the parent acid copolymer by one or more neutralizing agents.

The “amine-neutralized ionomer” refers to an ionomer, wherein the neutralizing agent(s) includes at least one amine.

The amine-neutralized ionomer used here may be derived from a parent acid copolymer comprising copolymerized units of an α-olefin having 2 to 10 carbons and an α,β-ethylenically unsaturated carboxylic acid having 3 to 8 carbons. Preferably, the parent acid copolymer comprises, based on the total weight of the acid copolymer, about 9 to about 35 wt %, or more preferably about 15 to about 35 wt %, or yet more preferably about 19 to about 30 wt %, or yet more preferably about 20 to about 25 wt %, or most preferably about 20 to about 23 wt %, of copolymerized units of the α,β-ethylenically unsaturated carboxylic acid, based on the total weight of the parent acid copolymer.

Suitable α-olefin comonomers may include, but are not limited to, ethylene, propylene, 1-butene, 1-pentene, 1-hexene, 1-heptene, 3 methyl-1-butene, 4-methyl-1-pentene, and the like and mixtures of two or more thereof. Preferably, the α-olefin is ethylene.

Suitable α,β-ethylenically unsaturated carboxylic acid comonomers may include, but are not limited to, acrylic acids, methacrylic acids, itaconic acids, maleic acids, maleic anhydrides, fumaric acids, monomethyl maleic acids, and mixtures of two or more thereof. Preferably, the α,β-ethylenically unsaturated carboxylic acid is selected from acrylic acids, methacrylic acids, and mixtures of two or more thereof.

The parent acid copolymers may further comprise copolymerized units of other comonomer(s), such as unsaturated carboxylic acids having 2 to 10, or preferably 3 to 8 carbons or derivatives thereof. Suitable acid derivatives include acid anhydrides, amides, and esters. Esters are preferred. Specific examples of preferred esters of unsaturated carboxylic acids include, but are not limited to, methyl acrylates, methyl methacrylates, ethyl acrylates, ethyl methacrylates, propyl acrylates, propyl methacrylates, isopropyl acrylates, isopropyl methacrylates, butyl acrylates, butyl methacrylates, isobutyl acrylates, isobutyl methacrylate, tert-butyl acrylates, tert-butyl methacrylates, octyl acrylates, octyl methacrylates, undecyl acrylates, undecyl methacrylates, octadecyl acrylates, octadecyl methacrylates, dodecyl acrylates, dodecyl methacrylates, 2-ethylhexyl acrylates, 2-ethylhexyl methacrylates, isobornyl acrylates, isobornyl methacrylates, lauryl acrylates, lauryl methacrylates, 2-hydroxyethyl acrylates, 2-hydroxyethyl methacrylates, glycidyl acrylates, glycidyl methacrylates, poly(ethylene glycol)acrylates, poly(ethylene glycol)methacrylates, poly(ethylene glycol) methyl ether acrylates, poly(ethylene glycol) methyl ether methacrylates, poly(ethylene glycol) behenyl ether acrylates, poly(ethylene glycol) behenyl ether methacrylates, poly(ethylene glycol) 4-nonylphenyl ether acrylates, poly(ethylene glycol) 4-nonylphenyl ether methacrylates, poly(ethylene glycol) phenyl ether acrylates, poly(ethylene glycol) phenyl ether methacrylates, dimethyl maleates, diethyl maleates, dibutyl maleates, dimethyl fumarates, diethyl fumarates, dibutyl fumarates, dimenthyl fumarates, vinyl acetates, vinyl propionates, and mixtures of two or more thereof. Examples of other suitable comonomers include, but are not limited to, methyl acrylates, methyl methacrylates, butyl acrylates, butyl methacrylates, glycidyl methacrylates, vinyl acetates, and mixtures of two or more thereof.

The parent acid copolymers may be polymerized as disclosed in U.S. Pat. Nos. 3,404,134; 5,028,674; 6,500,888; and 6,518,365.

To obtain the amine-neutralized ionomers, the parent acid copolymers are neutralized with one or more neutralizing agents to a level of about 1% to about 90%, or about 5% to about 50%, or about 5% to about 30%, based on the total carboxylic acid content of the parent acid copolymers, and wherein the neutralizing agents include at least one amine. The amines may be aliphatic or cycloaliphatic. They may be diamines, triamines, or polyamines. They may incorporate primary amine functions, secondary amine functions, or mixtures thereof. Preferably, the amine component incorporates primary amine functions. Without wishing to be held to any theory, it is believed that primary amines provide the strongest interaction, based on stereochemical considerations. Preferably, the amine component comprises 2 to 100, or 2 to 50 carbons. Specific examples of preferable amines include, but are not limited to, ethylene diamine, 1,3-diaminopropane, 1,2-diaminopropane, 1,4-diaminobutane, 1,2-diamino-2-methylpropane, 1,3-diaminopentane, 1,5-diaminopentane, 2,2-dimethyl-1,3-propanediamine, 1,6-hexanediamine, 2-methyl-1,5-pentanediamine, 1,7-diaminoheptane, 1,8-diaminooctane, 1,9-diaminononane, 1,10-diaminodecane, 1,12-diaminododecane, bis(4-aminocyclohexyl)methane, diethylenetriamine, β,β′-diaminodiethyl ether, β,β′-diaminodiethyl thioether, 4,9-dioxa-1,12-dodecanediamine, 4,7,10-trioxa-1,13-tridecanediamine, N-(2-aminoethyl)-1,3-propanediamine, 3,3′diamino-N-methyldipropylamine, 3,3′-iminobispropylamine, spermidine, bis(hexamethylene)triamine, triethylenetetramine, N,N′-bis(3-aminopropyl)ethylenediamine, N,N′-bis(2-aminoethyl)-1,3-propanediamine, N,N′-bis(3-aminopropyl)-1,3-propanediamine, spermine, tris(2-aminoethyl)amine, tetraethylenepentamine, pentaethylenehexamine, 1,3-diaminomethylxylene, 4,4′-methylenebis(2-methylcyclohexylamine), 1,2-diaminocyclohexane, 1,3-diaminocyclohexane. 1,4-diaminocyclohexane, bis(1,3-aminomethyl)cyclohexane, isophorone diamine, 1,8-diamino-p-menthane, piperazine, 4,4′-trimethylenedipiperidine, polyethylenimine, poly(vinyl amine), poly(allyl amine) and mixtures of two or more thereof. The neutralizing agents may further include one or more metal ions. Such amine-neutralized ionomers may be obtained by neutralizing the parent acid copolymers first with metal ion(s) and then subsequently with amine(s), or by neutralizing the parent acid copolymers first with amine(s) and then subsequently with metal ion(s), or by co-neutralizing the parent acid copolymers with a mixture of amine(s) and metal ion(s). Preferably, the amine-neutralized ionomers are obtained by neutralizing the parent acid copolymers first with metal ion(s) and then subsequently with amine(s), or by co-neutralizing the parent acid copolymers with a mixture of amine(s) and metal ion(s). More preferably, the amine-neutralized ionomers are obtained by co-neutralizing the parent acid copolymers with a mixture of amine(s) and metal ion(s). The metal ions may be monovalent, divalent, trivalent, multivalent, and mixtures of two or more thereof. Suitable monovalent metal ions include, but are not limited to, sodium, potassium, lithium, silver, mercury, copper, and mixtures of two or more thereof. Suitable divalent metal ions include, but are not limited to, beryllium, magnesium, calcium, strontium, barium, copper, cadmium, mercury, tin, lead, iron, cobalt, nickel, zinc, and mixtures of two or more thereof. Suitable trivalent metal ions include, but are not limited to, aluminum, scandium, iron, yttrium, and mixtures of two or more thereof. Suitable multivalent metal ions include, but are not limited to, titanium, zirconium, hafnium, vanadium, tantalum, tungsten, chromium, cerium, iron, and mixtures of two or more thereof. It is noted that when the metal ion is multivalent, complexing agents, such as stearate, oleate, salicylate, and phenolate radicals are included, as disclosed within U.S. Pat. No. 3,404,134. Preferably, the metal ions are selected from sodium, lithium, magnesium, zinc, and mixtures of two of more thereof. More preferably, the metal ion is zinc.

In a preferred embodiment, the amine-neutralized ionomer is neutralized with a minor amount of the amine(s) and a major amount of the metal ion(s). For example, to obtain the preferred amine-neutralized ionomers, the parent acid copolymers are neutralized with one or more amines to a level of about 1% to about 10% or preferably about 5% to about 10%, and with zinc ions to a level of about 10% to about 40% or preferably about 20% to about 30%, based on the total carboxylic acid content of the parent acid copolymers. This provides an optimized ionomer with the amine-neutralization providing enhanced clarity and the zinc-neutralization providing reduced moisture sensitivity tailored for use as solar cell encapsulants.

The degree of neutralization may be calculated from the amount of the neutralizing agent(s) added to a copolymer of known acid content, or it may be directly measured through established analytical methods, as described in, e.g., U.S. Pat. No. 3,328,367. Or, the degree of neutralization may be calculated based on the changes in the infrared absorption spectrum of the copolymer, as described in U.S. Pat. No. 3,471,460.

Any suitable process known or yet to be known within the art may be used to neutralize the parent acid copolymers. For example, the parent acid copolymer may be dissolved in a suitable solvent and then mixed with the neutralizing agent(s) or a solution of the neutralizing agent(s), as disclosed within U.S. Pat. No. 3,471,460. Alternatively, the neutralization of the parent acid copolymer may take place in slurry, as disclosed in U.S. Pat. No. 3,404,134. Preferably, the parent acid copolymer is neutralized through melt compounding processes.

Amine-neutralized ionomer may also be blended with an acid copolymer or a partially neutralized ionomer to obtain a proper level of neutralization.

The parent acid copolymers and the amine-neutralized ionomers derived therefrom may have a melting index (MI) of any level. However, it is recognized that the neutralization with amine(s) typically reduces the MI for the resulting amine-neutralized ionomers by at least 10% from that of the parent acid copolymers or the metal-neutralized ionomers from which the amine-neutralized ionomers are derived. Metal-neutralized ionomer compositions further comprising hindered amine light stabilizers (HALS) have been used as solar cell encapsulants, see, e.g., U.S. Pat. Nos. 5,478,402 and 5,476,553. However, it is well known within the art, when the amine is sterically hindered, such as in HALS additives, it can not function to further neutralize the metal-neutralized ionomer and, in turn, to reduce the MI thereof. Therefore, the amine-neutralized ionomers disclosed herein are distinct from the metal-neutralized ionomer compositions that further comprise HALS additives.

In a preferred embodiment, the parent acid copolymer may have a MI of less than about 60 g/10 min, more preferably less than about 55 g/10 min, and most preferably less than about 50 g/10 min, or less than about 35 g/10 min, as determined by ASTM D1238 at 190° C. and 2.16 kg load, prior to neutralization, and the amine-neutralized ionomers may have a MI of less than about 10 g/10 min, more preferably less than about 5 g/10 min, yet more preferably less than about 2.5 g/10 min, and most preferably less than about 1.5 g/10 min. In a further embodiment, when the amine-neutralized ionomers are meant to be cured, such as with organic peroxides, the MI is preferably less than about 150 g/10 min to allow melt compounding carried out at temperatures sufficiently low to avoid premature curing or crosslinking.

The amine-neutralized ionomer compositions may further comprise any suitable additives known within the art including plasticizers, processing aides, lubricants, flame retardants, impact modifiers, nucleating agents, antiblocking agents (e.g., silica), thermal stabilizers, UV absorbers, UV stabilizers, organic peroxides, dispersants, surfactants, chelating agents, coupling agents, adhesives, primers, or mixtures of two or more thereof. The total amount of additives comprised in a composition may be from about 0.001 up to about 5 wt %, based on the total weight of the composition.

The amine-neutralized ionomer composition may comprise one or more silane coupling agents to further enhance the adhesion strength of the encapsulant layer formed therefrom. Exemplary coupling agents include, but are not limited to, γ-chloropropylmethoxysilane, vinyltrimethoxysilane, vinyltriethoxysilane, vinyltris(β-methoxyethoxy)silane,γ-vinylbenzylpropyltrimethoxysilane, N-β-(N-vinyl benzylaminoethyl)-γ-aminopropyltrimethoxysilane, γ-methacryloxypropyltrimethoxysilane, vinyltriacetoxysilane, γ-glycidoxypropyltrimethoxysilane, γ-glycidoxypropyltriethoxysilane, β-(3,4-epoxycyclohexyl)ethyltrimethoxysilane, vinyltrichlorosilane, γ-mercaptopropylmethoxysilane, γ-aminopropyltriethoxysilane, N-β-(aminoethyl)-γ-aminopropyltrimethoxysilane, and mixtures of two or more thereof. The silane coupling agents are preferably present in the amine-neutralized ionomer compositions at a level of about 0.01 to about 5 wt %, or about 0.05 to about 1 wt %, based on the total weight of the compositions.

### Amine-Neutralized Ionomer Comprising Sheet or Film

The amine-neutralized ionomer comprising sheet or film may be in a single layer or multilayer form. By “single layer”, it is meant that the sheet or film is made of or consists essentially of the amine-neutralized ionomer composition. When in a multilayer form, at least one of the sub-layers is made of or consists essentially of the amine-neutralized ionomer composition, while the other sub-layer(s) may be made of any other suitable polymeric material(s), such as, acid copolymers, ionomers, poly(ethylene vinyl acetates), poly(vinyl acetals) (including acoustic grade poly(vinyl acetals)), polyurethanes, polyvinylchlorides, polyethylenes (e.g., linear low density polyethylenes), polyolefin block elastomers, poly(α-olefin-co-α,β-ethylenically unsaturated carboxylic acid ester) (e.g., poly(ethylene-co-methyl acrylate) and poly(ethylene-co-butyl acrylate)), silicone elastomers, epoxy resins, and combinations of two or more thereof. Preferably, at least one of the surface sub-layers of the multilayer film or sheet is made of or consists essentially of the amine-neutralized ionomer composition.

The total thickness of the sheet or film preferably may be in the range of about 2 mils (0.051 mm) and about 20 mils (0.51 mm). When the sheet or film is comprised in a flexible solar cell laminate as an encapsulant film layer, it is preferred to have a thickness of about 2 mils (0.051 mm) to about 10 mils (0.25 mm), or about 2 mils (0.051 mm) to about 5 mils (0.13 mm). When the sheet or film is comprised in a rigid solar cell laminate as an encapsulant sheet layer, it is preferred to have a thickness of about 10 mils (0.25 mm) to about 20 mils (0.51 mm).

The amine-neutralized ionomer comprising sheet or film may have a smooth or rough surface on one or both sides. Preferably, the sheet or film has rough surfaces on both sides to facilitate the deaeration of the laminate during the lamination process. Rough surfaces can be made by mechanically embossing or by melt fracture during extrusion of the sheets or films followed by quenching so that the roughness is retained during handling. The surface pattern can be applied to the film or sheet through common art processes. For example, the as-extruded film or sheet may be passed over a specially prepared surface of a die roll positioned in close proximity to the exit of the die which imparts the desired surface characteristics to one side of the molten polymer. Thus, when the surface of such a die roll has minute peaks and valleys, the polymer film or sheet cast thereon will have a rough surface on the side which contacts the roll which generally conforms respectively to the valleys and peaks of the roll surface. Such die rolls are disclosed in, e.g., U.S. Pat. No. 4,035,549 and US20030124296.

The amine-neutralized ionomer comprising sheets or films can be produced by any suitable process. For example, the films or sheets may be formed through dipcoating, solution casting, compression molding, injection molding, lamination, melt extrusion, blown film, extrusion coating, tandem extrusion coating, or any other procedures that are known to those of skill in the art. Preferably, the films or sheets are formed by melt extrusion, melt coextrusion, melt extrusion coating, or tandem melt extrusion coating processes.

### Solar Cell Pre-lamination Assemblies and Solar Cell Laminates Prepared Therefrom

A solar cell pre-lamination assembly comprises at least one layer of the amine-neutralized ionomer comprising sheet or film and a solar cell component comprised of one or a plurality of solar cells.

Solar cell is meant to include any article which can convert light into electrical energy. Within the solar cell pre-lamination assemblies, it is preferred that the solar cells are electronically interconnected. Examples of the various forms of solar cells include, for example, single crystal silicon solar cells, polycrystal silicon solar cells, microcrystal silicon solar cells, amorphous silicon based solar cells, copper indium selenide solar cells, compound semiconductor solar cells, dye sensitized solar cells, and the like. The most common types of solar cells include multi-crystalline solar cells, thin film solar cells, compound semiconductor solar cells and amorphous silicon solar cells.

Thin film solar cells are typically produced by depositing several thin film layers onto a substrate, such as glass or a flexible film, with the layers being patterned so as to form a plurality of individual cells which are electrically interconnected to produce a suitable voltage output. Depending on the sequence in which the multi-layer deposition is carried out, the substrate may serve as the rear surface or as a front window for the solar cell module. Thin film solar cells are disclosed in U.S. Pat. Nos. 5,512,107; 5,948,176; 5,994,163; 6,040,521; 6,137,048; and 6,258,620.

The solar cell pre-lamination assembly typically comprises at least one layer of the amine-neutralized ionomer comprising sheet or film, which is positioned next to the solar cell component and serves as one of the encapsulant layers, or preferably, the sheet or film is positioned next to the light-receiving side of solar cell component and serves as the front encapsulant layer.

The solar cell pre-lamination assembly may further comprise encapsulant layers formed of other polymeric materials, such as acid copolymers, ionomers, poly(ethylene vinyl acetates), poly(vinyl acetals) (including acoustic grade poly(vinyl acetals)), polyurethanes, polyvinylchlorides, polyethylenes (e.g., linear low density polyethylenes), polyolefin block elastomers, poly(α-olefin-co-α,β-ethylenically unsaturated carboxylic acid ester) (e.g., poly(ethylene-co-methyl acrylate) and poly(ethylene-co-butyl acrylate)), silicone elastomers, epoxy resins, and combinations of two or more thereof. Preferably, the solar cell pre-lamination assembly comprises two layers of the amine-neutralized ionomer comprising sheet or film, wherein each of the two layers is laminated to each of the two sides of the solar cell component and serves as the front or back encapsulant layer.

The thickness of the individual encapsulant layers other than the amine-neutralized ionomer comprising sheet(s) or films(s) may independently range from about 1 mil (0.026 mm) to about 120 mils (3 mm), or preferably from about 1 mil to about 40 mils (1.02 mm), or more preferably from about 1 mil to about 20 mils (0.51 mm). All the encapsulant layer(s) comprised in the solar cell pre-lamination assemblies may have smooth or rough surfaces. Preferably, the encapsulant layer(s) have rough surfaces to facilitate the deaeration of the laminates through the lamination process.

The solar cell pre-lamination assembly may yet further comprise an incident layer and/or a backing layer serving as the outer layers of the assembly at the light-receiving side and the back side, respectively.

The outer layers of the solar cell pre-lamination assemblies, i.e., the incident layer and the backing layer, may be derived from any suitable sheets or films. Suitable sheets may be glass or plastic sheets, such as polycarbonates, acrylics, polyacrylates, cyclic polyolefins (e.g., ethylene norbornene polymers), polystyrenes (preferably metallocene-catalyzed polystyrenes), polyamides, polyesters, fluoropolymers, or combinations of two or more thereof. In addition, metal sheets, such as aluminum, steel, galvanized steel, or ceramic plates may be utilized in forming the backing layer.

The term “glass” includes not only window glass, plate glass, silicate glass, sheet glass, low iron glass, tempered glass, tempered CeO— free glass, and float glass, but also colored glass, specialty glass (such as those containing ingredients to control solar heating), coated glass (such as those sputtered with metals (e.g., silver or indium tin oxide) for solar control purposes), E-glass, Toroglass, Solex® glass (PPG Industries, Pittsburgh, Pa.) and Starphire® glass (PPG Industries). Such specialty glasses are disclosed in, e.g., U.S. Pat. Nos. 4,615,989; 5,173,212; 5,264,286; 6,150,028; 6,340,646; 6,461,736; and 6,468,934. The type of glass to be selected for a particular assembly may depend on the intended use.

Suitable film layers may be polymers that include but are not limited to, polyesters (e.g., poly(ethylene terephthalate) and poly(ethylene naphthalate)), polycarbonate, polyolefins (e.g., polypropylene, polyethylene, and cyclic polyloefins), norbornene polymers, polystyrene (e.g., syndiotactic polystyrene), styrene-acrylate copolymers, acrylonitrile-styrene copolymers, polysulfones (e.g., polyethersulfone, polysulfone, etc.), nylons, poly(urethanes), acrylics, cellulose acetates (e.g., cellulose acetate, cellulose triacetates, etc.), cellophane, poly(vinyl chlorides) (e.g., poly(vinylidene chloride)), fluoropolymers (e.g., polyvinyl fluoride, polyvinylidene fluoride, polytetrafluoroethylene, ethylene-tetrafluoroethylene copolymers, etc.) and combinations of two or more thereof. The polymeric film may be bi-axially oriented polyester film (preferably poly(ethylene terephthalate) film) or a fluoropolymer film (e.g., Tedlar®, Tefzel®, and Teflon® films, from E. I. du Pont de Nemours and Company, Wilmington, Del. (DuPont)). Fluoropolymer-polyester-fluoropolymer (e.g., “TPT”) films are also preferred for some applications. Metal films, such as aluminum foil may also be used as the backing layer.

The solar cell pre-lamination assembly may further comprise other functional film or sheet layers (e.g., dielectric layers or barrier layers) embedded within the assembly. Such functional layers may be derived from any of the above mentioned polymeric films or those that are coated with additional functional coatings. For example, poly(ethylene terephthalate) films coated with a metal oxide coating, such as those disclosed within U.S. Pat. No. 6,521,825 and U.S. Pat. No. 6,818,819 and European Pat No. EP1182710, may function as oxygen and moisture barrier layers in the laminates.

If desired, a layer of nonwoven glass fiber (scrim) may also be included in the solar cell pre-lamination assembly to facilitate deaeration during the lamination process or to serve as reinforcement for the encapsulant layer(s). The use of such scrim layers within solar cell laminates is disclosed within, e.g., U.S. Pat. Nos. 5,583,057; 6,075,202; 6,204,443; 6,320,115; and 6,323,416 and European Pat No. EP0769818.

The film or sheet layers positioned to the light-receiving side of the solar cell component are preferably made of transparent material to allow efficient transmission of sunlight into the solar cell component. A special film or sheet may be included to serve both the function of an encapsulant layer and an outer layer. It is also conceivable that any of the film or sheet layers included in the assembly may be in the form of a pre-formed single-layer or multi-layer film or sheet.

If desired, one or both surfaces of the laminate layers of the solar cell pre-lamination assemblies may be treated to enhance the adhesion strength, as described above.

The solar cell pre-lamination assemblies may take any form known within the art. Preferable specific solar cell pre-lamination constructions (top (light receiving) side to back side) include,
glass/Al/solar cell/Al/glass;
glass/Al/solar cell/Al/fluoropolymer film (e.g., Tedlar® film);
fluoropolymer film/Al/solar cell/Al/glass;
fluoropolymer film/Al/solar cell/AI/fluoropolymer film;
glass/Al/solar cell/Al/polyester film (e.g., poly(ethylene terephthalate) film);
fluoropolymer film/Al/solar cell/Al/polyester film;
glass/Al/solar cell/Al/barrier coated film/Al/glass;
fluoropolymer film/Al/barrier coated film/Al/solar cell/Al/barrier coated film/Al/fluoropolymer film;
glass/Al/solar cell/Al/aluminum stock;
fluoropolymer film/Al/solar cell/Al/aluminum stock;
glass/Al/solar cell/Al/galvanized steel sheet;
glass/Al/solar cell/Al/polyester film/Al/aluminum stock;
fluoropolymer film/Al/solar cell/Al/polyester film/Al/aluminum stock;
glass/Al/solar cell/Al/polyester film/Al/galvanized steel sheet;
fluoropolymer film/Al/solar cell/Al/polyester film/Al/galvanized steel sheet;
glass/Al/solar cell/poly(vinyl butyral) encapsulant layer/glass;
glass/Al/solar cell/poly(vinyl butyral) encapsulant layer/fluoropolymer film;
fluoropolymer film/Al/solar cell/acid copolymer encapsulant layer/fluoropolymer film;
glass/Al/solar cell/ethylene vinyl acetate encapsulant layer/polyester film;
fluoropolymer film/Al/solar cell/poly(ethylene-co-methyl acrylate) encapsulant layer/polyester film;
glass/poly(ethylene-co-butyl acrylate) encapsulant layer/solar cell/Al/barrier coated film/poly(ethylene-co-butyl acrylate) encapsulant layer/glass;
   and the like, wherein “Al” stands for the amine-neutralized ionomer comprising sheet or film. In addition, besides the Tedlar® film from DuPont, suitable fluoropolymer films also include TPT trilayer films.

The invention further provides solar cell laminates or modules prepared from the solar cell pre-lamination assemblies disclosed above. Specifically the solar cell laminates are formed by subjecting the solar cell pre-lamination assemblies to further lamination process, as provided below in detail. When compared to the solar cell laminates disclosed by prior art, the solar cell laminates of the invention possess improved transparency and thermostability due to the inclusion of amine-neutralized ionomer comprising sheets or films as encapsulant layers.

### Lamination Process

Any lamination process known within the art may be used to prepare the solar cell laminates from the solar cell pre-lamination assembly. The lamination process may be an autoclave or non-autoclave process.

In an exemplary process, the component layers of a pre-lamination solar cell assembly are stacked up in the desired order to form a pre-lamination assembly. The assembly is then placed into a bag capable of sustaining a vacuum (“a vacuum bag”), the air is drawn out of the bag by a vacuum line or other means, the bag is sealed while the vacuum is maintained (e.g., about 27-28 in Hg (689-711 mm Hg)), and the sealed bag is placed in an autoclave at a pressure of about 150 to about 250 psi (about 11.3-18.8 bar), a temperature of about 130° C. to about 180° C., or about 120° C. to about 160° C., or about 135° C. to about 160° C., or about 145° C. to about 155° C., for about 10 to about 50 minutes, or about 20 to about 45 minutes, or about 20 to about 40 minutes, or about 25 to about 35 minutes. A vacuum ring may be substituted for the vacuum bag. One type of suitable vacuum bag is disclosed within U.S. Pat. No. 3,311,517. Following the heat and pressure cycle, the air in the autoclave is cooled without adding additional gas to maintain pressure in the autoclave. After about 20 minutes of cooling, the excess air pressure is vented and the laminates are removed from the autoclave.

Alternatively, the pre-lamination assembly may be heated in an oven at about 80° C. to about 120° C., or about 90° C. to about 100° C., for about 20 to about 40 minutes, and thereafter, the heated assembly is passed through a set of nip rolls so that the air in the void spaces between the individual layers may be squeezed out, and the edge of the assembly sealed. The assembly at this stage is referred to as a pre-press.

The pre-press may then be placed in an air autoclave where the temperature is raised to about 120° C. to about 160° C., or about 135° C. to about 160° C., at a pressure of about 100 to about 300 psi (about 6.9 to about 20.7 bar), or about 200 psi (13.8 bar). These conditions are maintained for about 15 to about 60 minutes, or about 20 to about 50 minutes, and after which, the air is cooled while no more air is added to the autoclave. After about 20 to about 40 minutes of cooling, the excess air pressure is vented, the laminated products are removed from the autoclave.

The solar cell laminates may also be produced through non-autoclave processes. Such non-autoclave processes are disclosed, for example, within U.S. Pat. Nos. 3,234,062; 3,852,136; 4,341,576; 4,385,951; 4,398,979; 5,536,347; 5,853,516; 6,342,116; and 5,415,909, US20040182493, EP1235683 B1, WO9101880 and WO03057478. Generally, the non-autoclave processes include heating the pre-lamination assembly and the application of vacuum, pressure or both. For example, the assembly may be successively passed through heating ovens and nip rolls.

This should not be considered limiting. Essentially any lamination process may be used.

### EXAMPLES

The following Examples are intended to be illustrative of the invention, and are not intended in any way to limit the scope of the invention.

### Lamination Process 1

The component layers of the laminate are stacked to form a pre-lamination assembly. For the assembly containing a polymeric film layer as the outer surface layer, a cover glass sheet is placed over the film layer. The pre-lamination assembly is then placed within a Meier ICOLAM® 10/08 laminator (Meier laminator; Meier Vakuumtechnik GmbH, Bocholt, Germany). The lamination cycle includes an evacuation step (vacuum of 3 in Hg (76 mm Hg)) of 5.5 minutes and a pressing stage (pressure of 1000 mbar) of 5.5 minutes at a temperature of 145° C. The resulting laminate is then removed from the laminator.

### Lamination Process 2

The component layers of the laminate are stacked to form a pre-lamination assembly. For the assembly containing a polymeric film layer as the outer surface layer, a cover glass sheet is placed over the film layer. The pre-lamination assembly is then placed within a vacuum bag, which is sealed and a vacuum is applied to remove the air from the vacuum bag. The bag is placed into an oven and heated to about 90° C. to about 100° C. for 30 minutes to remove any air contained between the assembly. The assembly is then subjected to autoclaving at 140° C. for 30 minutes in an air autoclave to a pressure of 200 psig (14.3 bar). The air is cooled while no more air is added to the autoclave. After 20 minutes of cooling and when the air temperature reaches less than about 50° C., the excess pressure is vented and the vacuum bag containing the laminated assembly is removed from the autoclave. The resulting laminate is then removed from the vacuum bag.

### Materials

The following films and sheets are used in the examples:
AL is a 3.2 mm thick aluminum sheet that is 5052 alloyed with 2.5 wt % of magnesium and conforms to Federal specification QQ-A-250/8 and ASTM B209;
EVA is SC50B, believed to be a formulated composition based on poly(ethylene-co-vinyl acetate) in the form of a 20 mil thick (0.51 mm) sheet (Hi-Sheet Industries, Japan);
FPF is a 1.5 mil (0.038 mm) thick corona surface treated Tedlar® film (DuPont);
Glass 1 is 2.5 mm thick float glass;
Glass 2 is a 3.0 mm thick clear annealed float glass plate layer;
Glass 3 is a 3.0 mm thick Solex® solar control glass from the PPG Industries, Pittsburgh, Pa.;
Glass 4 is Starphire® glass from the PPG Industries;
ION 1 is a 60 mil (1.52 mm) thick embossed sheet made of Ionomer A, which has a MI of approximately 2 g/10 min and is derived from a poly(ethylene-co-methacrylic acid) that contains, based on the total weight of the acid copolymer, 22 wt % copolymerized units of methacrylic acid, and has 27% of its total carboxylic acid content neutralized with sodium ion;
ION 2 is a 20 mil (0.51 mm) thick embossed sheet made of Ionomer B, which has a MI of 2 g/10 min and is derived from a poly(ethylene-co-methacrylic acid) that contains, based on the total weight of the acid copolymer, 19 wt % copolymerized units of methacrylic acid, and has 37% of its total carboxylic acid content neutralized with zinc ion;
ION 3 is a 20 mil (0.51 mm) thick embossed sheet made of Surlyn®9950 (DuPont);
PET 1 is a 7 mils (0.18 mm) thick poly(allyl amine)-primed, biaxially-oriented poly(ethylene terephthalate) film layer;
PET 2 is a XIR®-70 HP Auto film (Southwall Company, Palo Alto, Calif.);
PET 3 is a XIR®-75 Auto Blue V-1 film (Southwall);
PET 4 is a Soft Look® UV/IR 25 solar control film (Tomoegawa Paper Company, Ltd., Tokyo, Japan);
PET 5 is a XIR®-75 Green film (Southwall);
PET 6 is RAYBARRIER® TFK-2583 solar control film (Sumitomo Osaka Cement, Japan);
PVB-A is a 20 mil thick (0.51 mm) embossed sheet of an acoustic grade of poly(vinyl butyral);
PVB-B is B51V, believed to be a formulated composition based on poly(vinyl butyral) in the form of a 20 mil thick (0.51 mm) sheet (DuPont);
Solar Cell 1 is a 10×10 in (254×254 mm) amorphous silicon photovoltaic device comprising a stainless steel substrate (125 μm thick) with an amorphous silicon semiconductor layer (see, e.g., U.S. Pat. No. 6,093,581, Example 1);
Solar Cell 2 is a 10×10 in (254×254 mm) copper indium diselenide (CIS) photovoltaic device (see, e.g., U.S. Pat. No. 6,353,042, column 6, line 19);
Solar Cell 3 is a 10×10 in (254×254 mm) cadmium telluride (CdTe) photovoltaic device (see, e.g., U.S. Pat. No. 6,353,042, column 6, line 49);
Solar Cell 4 is a silicon solar cell made from a 10×10 in (254×254 mm) polycrystalline EFG-grown wafer (see, e.g., U.S. Pat. No. 6,660,930, column 7, line 61);
Al 1 is a 20 mil (0.51 mm) thick embossed sheet made from an amine-neutralized ionomer, which has a MI of 5 g/10 min and is derived from a poly(ethylene-co-methacrylic acid) comprising, based on the total weight of the acid copolymer, 20 wt % copolymerized units of methacrylic acid and having 20% of its total carboxylic acid content neutralized with bis(1,3-aminomethyl)cyclohexane;
Al 2 is a 20 mil (0.51 mm) thick embossed sheet made of a composition comprising, based on the total weight of the composition, 99.85 wt % of an amine-neutralized ionomer and 0.15 wt % of TINUVIN 328 (Ciba Specialty Chemicals, Tarrytown, N.Y.), wherein the amine-neutralized ionomer has a MI of 1 g/10 min and is derived from a poly(ethylene-co-methacrylic acid) comprising, based on the total weight of the acid copolymer, 21 wt % copolymerized units of methacrylic acid and having 30% of its total carboxylic acid content neutralized with diethylenetriamine;
Al 3 is a 15 mil (0.38 mm) thick embossed sheet made from an amine-neutralized ionomer, which has a MI of 2.5 g/10 min and is derived from a poly(ethylene-co-methacrylic acid) comprising, based on the total weight of the acid copolymer, 20 wt % copolymerized units of methacrylic acid and having 5% of its total carboxylic acid content neutralized with bis(1,3-aminomethyl)cyclohexane and 20% of its total carboxylic acid content neutralized with zinc ions;
Al 4 is a 20 mil (0.51 mm) thick embossed sheet made from an amine-neutralized ionomer, which has a MI of 1.5 g/10 min and is derived from a poly(ethylene-co-methacrylic acid) having, based on the total weight of the acid copolymer, 22 wt % copolymerized units of methacrylic acid and having 2.5% of its total carboxylic acid content neutralized with isophorone diamine and 30% of its total carboxylic acid content neutralized with zinc ions;
Al 5 is a 20 mil (0.51 mm) thick embossed trilayer sheet having two 2 mil (0.06 mm) thick surface sub-layers made of a composition comprising, based on the total weight of the composition, 99.5 wt % of an amine-neutralized ionomer and 0.5 wt % of CYASORB UV-1164 (Cytec Industries Inc., West Paterson, N.J.) and an inner sub-layer made of Surlyn® 1705 (DuPont), wherein the amine-neutralized ionomer has a MI of 2.5 g/10 min and is derived from a poly(ethylene-co-methacrylic acid) containing, based on the total weight of the acid copolymer, 22 wt % copolymerized units of methacrylic acid and having 25% of its total carboxylic acid content neutralized with bis(1,3-aminomethyl)cyclohexane.
Al 6 is a 20 mil (0.51 mm) thick embossed trilayer sheet having two 2 mil (0.06 mm) thick surface sub-layers made of a composition comprising, based on the total weight of the composition, 99.75 wt % of an amine-neutralized ionomer and 0.5 wt % of CYASORB UV-1164 (Cytec Industries Inc) and an inner sub-layer made of Surlyn® 8140 (DuPont), wherein the amine-neutralized ionomer has a MI of 3.0 g/10 min and is derived from a poly(ethylene-co-methacrylic acid) comprising, based on the total weight of the acid copolymer, 20 wt % copolymerized units of methacrylic acid and having 7.5% of its total carboxylic acid content neutralized with hexamethylenediamine and 20% of its total carboxylic acid content neutralized with zinc ions;
Al 7 is a 20 mil (0.51 mm) thick embossed trilayer sheet having two 2 mil (0.06 mm) thick surface sub-layers made of Nucrel® RX9-1 (DuPont) and an inner sub-layer made from an amine-neutralized ionomer, wherein the amine-neutralized ionomer has a MI of 2 g/10 min and is derived from a poly(ethylene-co-methacrylic acid) comprising, based on the total weight of the acid copolymer, 21 wt % copolymerized units of methacrylic acid and having 5% of its total carboxylic acid content neutralized with 1,4-diaminobutane and 25% of its total carboxylic acid content neutralized with zinc ions;
Al 8 is a 20 mil (0.51 mm) thick embossed bilayer sheet having a first 3 mil (0.09 mm) thick sub-layer made of an amine-neutralized ionomer and a second sub-layer made of Surlyn® 8940 (DuPont), wherein the amine-neutralized ionomer has a MI of 2.5 g/10 min and is derived from a poly(ethylene-co-methacrylic acid) comprising, based on the total weight of the acid copolymer, 22 wt % copolymerized units of methacrylic acid and having 30% of its total carboxylic acid content neutralized with bis(1,3-aminomethyl)cyclohexane;
Al 9 is a 20 mil (0.51 mm) thick embossed bilayer sheet having a first 18 mil (0.46 mm) thick sub-layer made of an amine-neutralized ionomer and a second sub-layer made of Surlyn® 9120 (DuPont), wherein the amine-neutralized ionomer has a MI of 1 g/10 min and is derived from a poly(ethylene-co-methacrylic acid) comprising, based on the total weight of the acid copolymer, 20 wt % copolymerized units of methacrylic acid and having 3% of its total carboxylic acid content neutralized with triethylenetetraamine and 28% of its total carboxylic acid content neutralized with zinc ions;
TPT is a Akasol® PTL 3-38/75 film layer (Akasol® film layer; August Krempel Soehne GmbH & Co., Germany) described as a 7 mil thick white poly(vinylidene fluoride)/poly(ethylene terephthalate)/poly(vinylidene fluoride) tri-layer film with primer.

### Examples 1-14

A series of 12×12 in (305×305 mm) solar cell laminate structures described below in Table 1 are assembled and laminated by Lamination Process 1. Layers 1 and 2 constitute the incident layer and the front encapsulant layer, respectively, and Layers 4 and 5 constitute the back encapsulant layer and the backing layer, respectively.

TABLE 1

| | Lamination Structure | | | | |
|---|---|---|---|---|---|
| Example | Layer 1 | Layer 2 | Layer 3 | Layer 4 | Layer 5 |
| 1, 15 | Glass 4 | Al 1 | Solar Cell 1 | Al 1 | FPF |
| 2, 16 | Glass 4 | Al 2 | Solar Cell 2 | Al 2 | Glass 1 |
| 3, 17 | Glass 4 | Al 3 | Solar Cell 3 | Al 3 | TPT |
| 4, 18 | Glass 4 | Al 4 | Solar Cell 4 | Al 4 | Glass 1 |
| 5, 19 | FPF | Al 5 | Solar Cell 1 | Al 1 | AL |
| 6, 20 | Glass 4 | EVA | Solar Cell 2 | Al 4 | Glass 1 |
| 7, 21 | FPF | Al 6 | Solar Cell 1 | Al 6 | FPF |
| 8, 22 | Glass 1 | Al 7 | Solar Cell 2 | PVB | PET 1 |
| 9, 23 | Glass 4 | Al 8 | Solar Cell 3 | Al 8 | TPT |
| 10, 24 | Glass 4 | Al 9 | Solar Cell 4 | ION 2 | AL |
| 11, 25 | Glass 4 | ION 3 | Solar Cell 1 | Al 3 | Glass 1 |
| 12, 26 | Glass 4 | Al 6 | Solar Cell 2 | Al 4 | FPF |
| 13, 27 | Glass 4 | Al 6 | Solar Cell 1 | PVB-A | Glass 1 |
| 14, 28 | Glass 4 | Al 9 | Solar Cell 4 | ION 1 | |

### Examples 15-28

A series of 12×12 in (305×305 mm) solar cell laminate structures described above in Table 1 are assembled and laminated by Lamination Process 2. Layers 1 and 2 constitute the incident layer and the front encapsulant layer, respectively, and Layers 4 and 5 constitute the back encapsulant layer and the backing layer, respectively.

1. A solar cell pre-lamination assembly comprising a film or sheet comprising an amine-neutralized ionomer composition and a solar cell component comprising or formed of one or a plurality of electronically interconnected solar cells, wherein,
(a) the solar cell component has a light-receiving side that faces a light source and a back side that is opposite from the light source; and
(b) the amine-neutralized ionomer is derived from an acid copolymer that (i) comprises, based on the total weight of the acid copolymer, copolymerized units of an α-olefin having 2 to 10 carbons and about 9 to about 35 wt % of an α,β-ethylenically unsaturated carboxylic acid having 3 to 8 carbons and (ii) is about 1% to about 90%, based on the total carboxylic acid content of the acid copolymer, neutralized with one or more neutralizing agents that include one or more amines.

2. The assembly of claim 1, wherein (a) the acid copolymer comprises about 20 to about 25 wt % of copolymerized units of the α,β-ethylenically unsaturated carboxylic acid, based on the total weight of the acid copolymer and is about 5% to about 50% neutralized, based on the total carboxylic acid content of the acid copolymer; and (b) the one or more amines are selected from the group consisting of diamines, triamines, polyamines, and mixtures of two or more thereof.

3. The assembly of claim 1, wherein the one or more amines are selected from the group consisting of ethylene diamine, 1,3-diaminopropane, 1,2-diaminopropane, 1,4-diaminobutane, 1,2-diamino-2-methylpropane, 1,3-diaminopentane, 1,5-diaminopentane, 2,2-dimethyl, 1,3-propanediamine, 1,6-hexanediamine, 2-methyl-1,5-pentanediamine, 1,7-diaminoheptane, 1,8-diaminooctane, 1,9-diaminononane, 1,10-diaminodecane, 1,12-diaminododecane, bis(4-aminocyclohexyl)methane, diethylenetriamine, β,β′-diaminodiethyl ether, β,β′-diaminodiethyl thioether, 4,9-dioxa-1,12-dodecanediamine, 4,7,10-trioxa-1,13-tridecanediamine, N-(2-aminoethyl)-1,3-propanediamine, 3,3′diamino-N-methyldipropylamine, 3,3′-iminobispropylamine, spermidine, bis(hexamethylene)triamine, triethylenetetramine, N,N′-bis(3-aminopropyl)ethylenediamine, N,N′-bis(2-aminoethyl)-1,3-propanediamine, N,N′-bis(3-aminopropyl)-1,3-propanediamine, spermine, tris(2-aminoethyl)amine, tetraethylenepentamine, pentaethylenehexamine, phenylene diethyl amine, 1,3-diaminomethylxylene, 4,4′-methylenebis(2-methylcyclohexylamine), 1,2-diaminocyclohexane, 1,3-diaminocyclohexane. 1,4-diaminocyclohexane, bis(1,3-aminomethyl)cyclohexane, isophorone diamine, 1,8-diamino-p-menthane, piperazine, 4,4′-trimethylenedipiperidine, and mixtures of two or more thereof.

4. The assembly of claim 1, wherein the neutralizing agents further include one or more metal ions.

5. The assembly of claim 4, wherein the acid copolymer is neutralized to a level of about 1% to about 10% with the one or more amines and a level of about 10% to about 40% with the one or more metal ions selected from the group consisting of sodium, lithium, magnesium, zinc, and mixtures of two or more thereof, based on the total carboxylic acid content of the acid copolymer.

6. The assembly of claim 1, wherein the film or sheet comprised of the amine-neutralized ionomer composition is in a monolayer form and is made of or consists essentially of the amine-neutralized ionomer composition.

7. The assembly of claim 1, wherein the film or sheet comprised of the amine-neutralized ionomer composition is in a multilayer form and comprises two or more sub-layers, and wherein at least one of the sub-layers is made of or consists essentially of the amine-neutralized ionomer composition and each of the other sub-layer(s) comprises or is made of a polymer material selected from the group consisting of acid copolymers, ionomers, poly(ethylene vinyl acetates), poly(vinyl acetals), polyurethanes, polyvinylchlorides, polyethylenes, polyolefin block elastomers, poly(α-olefin-co-α,β-ethylenically unsaturated carboxylic acid ester) copolymers, silicone elastomers, epoxy resins, and combinations of two or more thereof.

8. The assembly of claim 1, wherein the film or sheet comprised of the amine-neutralized ionomer composition has a total thickness of about 2 mils (0.051 mm) to about 20 mils (0.51 mm).

9. The assembly of claim 1, wherein the solar cell is selected from the group consisting of multi-crystalline solar cells, thin film solar cells, compound semiconductor solar cells, amorphous silicon solar cells, and combinations of two or more.

10. The assembly of claim 1, comprising a front encapsulant layer positioned next to the light-receiving side of the solar cell component and a back encapsulant layer positioned next to the back side of the solar cell component, wherein either the front encapsulant layer, the back encapsulant layer, or both are formed of the film or sheet comprised of the amine-neutralized ionomer composition.

11. The assembly of claim 7, wherein the film or sheet comprised of the amine-neutralized ionomer composition has a total thickness of about 2 mils (0.051 mm) to about 20 mils (0.51 mm).

12. The assembly of claim 7, wherein the solar cell is selected from the group consisting of multi-crystalline solar cells, thin film solar cells, compound semiconductor solar cells, amorphous silicon solar cells, and combinations of two or more.

13. The assembly of claim 7, comprising a front encapsulant layer positioned next to the light-receiving side of the solar cell component and a back encapsulant layer positioned next to the back side of the solar cell component, wherein either the front encapsulant layer, the back encapsulant layer, or both are formed of the film or sheet comprised of the amine-neutralized ionomer composition.

14. The assembly of claim 10, wherein the front encapsulant layer is formed of the film or sheet comprised of the amine-neutralized ionomer composition and the back encapsulant layer is formed of a polymeric material selected from the group consisting of acid copolymers, ionomers, poly(ethylene vinyl acetates), poly(vinyl acetals), polyurethanes, polyvinylchlorides, polyethylenes, polyolefin block elastomers, poly(α-olefin-co-α,β-ethylenically unsaturated carboxylic acid ester) copolymers, silicone elastomers, epoxy resins, and combinations thereof.

15. The assembly of claim 10, wherein each of the front encapsulant layer and the back encapsulant layer is formed of the film or sheet comprised of the amine-neutralized ionomer composition.

16. The assembly of claim 10, further comprising an incident layer positioned next to the front encapsulant layer and a backing layer positioned next to the back encapsulant layer.

17. The assembly of claim 16, wherein the incident layer is selected from the group consisting of (i) glass sheets, (ii) polymeric sheets comprising or formed of polycarbonates, acrylics, polyacrylates, cyclic polyolefins, polystyrenes, polyamides, polyesters, fluoropolymers, or combinations of two or more thereof, and (iii) polymeric films comprising or formed of polyesters, polycarbonate, polyolefins, norbornene polymers, polystyrene, styrene-acrylate copolymers, acrylonitrile-styrene copolymers, polysulfones, nylons, polyurethanes, acrylics, cellulose acetates, cellophane, poly(vinyl chlorides), fluoropolymers, or combinations of two or more thereof.

18. The assembly of claim 16, wherein the backing layer is selected from the group consisting of (i) glass sheets, (ii) polymeric sheets, (iii) polymeric films, (iv) metal sheets, and (v) ceramic plates, and wherein the polymeric sheets comprise or are formed of polycarbonates, acrylics, polyacrylates, cyclic polyolefins, polystyrenes, polyamides, polyesters, fluoropolymers, or combinations or two or more thereof; and the polymeric films comprise or are formed of polyesters, polycarbonates, polyolefins, norbornene polymers, polystyrenes, styrene-acrylate copolymers, acrylonitrile-styrene copolymers, polysulfones, nylons, polyurethanes, acrylics, cellulose acetates, cellophanes, poly(vinyl chlorides), fluoropolymers, or combinations of two or more thereof.

19. The assembly of claim 1, consisting essentially of, from a top side that faces the light source to a bottom side that is opposite from the light source, (i) an incident layer that is positioned next to, (ii) a front encapsulant layer that is positioned next to, (iii) the solar cell component that is positioned next to, (iv) a back encapsulant layer that is positioned next to, (v) a backing layer, wherein either the front encapsulant layer, the back encapsulant layer, or both comprise or are formed of the film or sheet comprised of the amine-neutralized ionomer composition.

20. A process comprising: (i) providing a solar cell pre-lamination assembly and (ii) laminating the assembly to form a solar cell module, wherein the assembly is as recited in claim 1.

21. The process of claim 20, wherein the assembly is as recited in claim 19.

22. The process of claim 20, wherein the laminating step is conducted by subjecting the assembly to heat.

23. The process of claim 22, wherein the laminating step further comprises subjecting the assembly to vacuum or pressure.

24. A solar cell module produced from a solar cell pre-lamination assembly, wherein the assembly is as recited in claim 1.

25. The module of claim 24, wherein the assembly is as recited in claim 19.
